(19) United States
(12) Patent Application Publication
(10) Pub. No.: US 2004/0188715 A1
(43) Pub. Date: Sep. 30, 2004

(54) Reinforced material

(76) Inventors: Yuri Leonidovich Spirin, Kidlington (GB); Vladimir Stepanovich Dubinin, Moscow (RU)

Correspondence Address: Wyatt, Tarrant & Combs, LLP, Suite 800, 1715 Aaron Brenner Dr., Memphis, TN, 38120-4367, US

(21) Appl. No.: 10/460,078

(22) Filed: Jun. 12, 2003

(30) Foreign Application Priority Data
Dec. 4, 2001 (WO) PCT/GB01/05366
Dec. 12, 2000 (GB) GB0030254.7

(51) Int. Cl. H01L 31/072

(52) U.S. Cl. 257/200

(57) ABSTRACT

A reinforced material comprising a solid body (1) having a plurality of intersecting holes formed therein and a plurality of elongate solid state reinforcing members (2) located within the holes, wherein the elongate solid state reinforcing members (2) are mutually joined by flexible joints (3) where they intersect with each other.

### CROSS-REFERENCE TO RELATED APPLICATION

This patent application claims priority from International Patent Application No. PCT/GB01/05366 filed Dec. 4, 2001, which claims priority from United Kingdom Patent No. GB2370587B filed Dec. 12, 2000, both or which are entitled “REINFORCED MATERIAL,” and the entire disclosures of both of which are hereby incorporated by reference in their entirety.

### STATEMENT REGARDING FEDERALLY SPONSORED RESEARCH OR

### DEVELOPMENT

### Not Applicable.

### FIELD OF THE INVENTION

The invention relates to a reinforced material having high strength and a resilient construction.

### BACKGROUND OF THE INVENTION

It is known from WO 00/40506 (EP 1156011) to provide a solid state material in which pores having a maximal diameter of 100 nm are formed in a surface layer of the material, and in which threads or filaments of the same or a different material are filled into the pores. The threads or filaments are substantially independent of each other and are not intersect.

It is known from RU 2056492 to provide a reinforced material made out of concrete having intersecting holes formed therein with elongate bars and longitudinal helical constructions serving as a reinforcement matrix. The components of the reinforcing matrix are rigidly welded together. This material does not possess sufficient strength and elasticity for many applications.

### SUMMARY OF THE INVENTION

According to a first aspect of the present invention, there is provided a reinforced material comprising a solid body having a plurality of intersecting holes formed therein and a plurality of elongate solid state reinforcing members located within the holes, characterised in that the elongate solid state reinforcing members are flexibly mutually joined where they intersect with each other, and wherein the holes and the elongate solid state reinforcing members have linear cross-sectional dimensions of less than 1 mm.

Preferably, the holes and the elongate solid state reinforcing members have linear cross-sectional dimensions (e.g. thicknesses or diameters or the like) on a nanometric scale, that is, less than 1 micrometre.

According to a second aspect of the present invention, there is provided a reinforced material comprising a solid body having a plurality of intersecting holes formed therein and a plurality of elongate solid state reinforcing members located within the holes, characterised in that the elongate solid state reinforcing members are flexibly mutually joined where they intersect with each other and wherein the elongate solid state reinforcing members are not affixed along their lengths to the solid state body.

For the avoidance of doubt, the holes and the elongate solid state reinforcing members of the second aspect of the present invention may have cross-sectional dimensions on both a micrometric or nanometric scale as well as a macroscopic scale.

In this way, embodiments of the present invention seek to provide an increase in the strength and elasticity of a reinforced material.

Although embodiments of the present invention are envisaged to be applicable to macroscopic structures such as reinforced concrete having, for example, metal reinforcing members formed therein, further embodiments of the present invention also relate to a reinforced material having reinforcements formed therein on a microscopic scale, more preferably a nanometric scale.

What is important is that the reinforcing members are flexibly joined where they intersect with each other, this flexibility serving to provide increased resilience of the reinforced material as compared to known reinforced materials including reinforcing members that are rigidly mutually connected, for example by way of welding. This increased resilience helps to allow the reinforced material to flex in response to applied stresses and thereby reduces the likelihood of destruction or damage.

In macroscopic embodiments, such as blocks of reinforced concrete, the reinforcing members may be mutually joined at their points of intersection by way of pivotable or hinge-like mechanical joints, or by way of magnetic, electromagnetic or electrostatic forces including interatomic, intermolecular or intramolecular forces, such as ionic, covalent or other chemical bonds or Van der Waal's forces, or by way of flexibly adhering the reinforcing members to each other at their points of intersection with a suitable adhesive compound that remains flexible when set.

In microscopic and nanometric embodiments, the reinforcing members may be mutually joined at their points of intersection through interatomic, intermolecular or intramolecular forces, including electrostatic and electromagnetic forces such as ionic, covalent or other chemical bonds or Van der Waal's forces, and also magnetic forces. Which of these forces is appropriate will generally be determined by the nature and composition of the reinforcing members. It is also possible to use a flexible adhesive compound to join the reinforcing members as discussed above in relation to macroscopic embodiments of the present invention.

In both the macroscopic and microscopic embodiments of the present invention, it is particularly preferred that the reinforcing members are not affixed to the solid state material along the lengths of the holes. One way of achieving this result is to ensure that there is a gap between an outer perimeter of the reinforcing members and an inner surface of the holes. This gap may be an air gap, or may be provided by slidably encasing the reinforcing members in sleeves before inserting them into the holes. The sleeves may be made out of a plastics material or any other suitable material. The sleeves are preferably configured so as to allow the reinforcing members to be flexibly joined at their intersections, and may thus be comprised as separate longitudinal sections.

For example, reinforced concrete is traditionally formed by assembling a skeletal framework of metal reinforcing members and then casting concrete about the reinforcing members. It will be apparent that in this traditional construction, the reinforcing members become immovably embedded in and adhered to the concrete. By providing a skeletal framework of flexibly mutually joined reinforcing members slidably retained within, say, plastics sleeves, it is possible to cast concrete about this framework so as to form a structure in which the reinforcing members do not adhere to the concrete but retain a degree of flexible movement in relation thereto.

The reinforced material of the present invention may be constructed by forming intersecting holes or pores in a solid body by any appropriate method. In one embodiment, reinforcing chains are then formed by linking together a series of lengths of solid state reinforcing members by way of flexible joints. A first set of reinforcing chains is then inserted into a first set of holes which extend in a first general direction through the solid body, followed by a second set of reinforcing chains which is inserted into a second set of holes which extend in a second general direction. The chains are then flexibly joined together where they intersect by way of the techniques discussed above.

In some embodiments, the flexible joints can be formed by applying a glue to the intersections between the reinforcing members, the glue being chosen so as to retain elasticity after it has set.

The intersecting holes may be in the form of pores.

Macroscopic and nanometric embodiments of the present invention may have particularly advantageous features when using particular construction materials. For example, the solid having the intersecting holes may be made from a dielectric material, a semiconductor material or a conductive material.

The elongate solid state reinforcing members may be made from a dielectric material, a semiconductor material or a conductive material.

The elongate solid state reinforcing members may be made partly from a dielectric material and partly from a semiconductor material.

The elongate solid state reinforcing members may be made partly from a dielectric material and partly from a conductive material.

The elongate solid state reinforcing members may be made partly from a semiconductor material and partly from a conductive material.

The elongate solid state reinforcing members may be made partly from a dielectric material, partly from a semiconductor material and partly from a conductive material.

Where a dielectric material is used, either for the solid body or for the reinforcing members, at least part of the dielectric material may be made of a ceramic material.

Where a conductive material is used, either for the solid body or for the reinforcing members, at least part of the conductive material may be made of silver.

Where a conductive material is used, either for the solid body or for the reinforcing members, at least part of the conductive material may be made of gold.

Where a conductive material is used, either for the solid body or for the reinforcing members, at least part of the conductive material may be made of platinum.

Where a conductive material is used, either for the solid body or for the reinforcing members, at least part of the conductive material may be made of copper.

The holes or pores and the elongate solid state reinforcing members may be formed with a cross-section or width of 10 to 200 nanometres.

The holes or pores and the elongate solid state reinforcing members may be formed with a length of 100 to 1000 nanometres.

### BRIEF DESCRIPTION OF THE DRAWINGS

For a better understanding of the present invention, and to show how it may be carried into effect, reference shall now be made by way of example to the accompanying drawing, in which:

FIG. 1 shows a schematic cross section through the reinforced material of a first embodiment of the present invention; and

FIG. 2 shows a schematic cross section through the reinforced material of a second embodiment of the present invention.

### DETAILED DESCRIPTION OF THE DRAWINGS

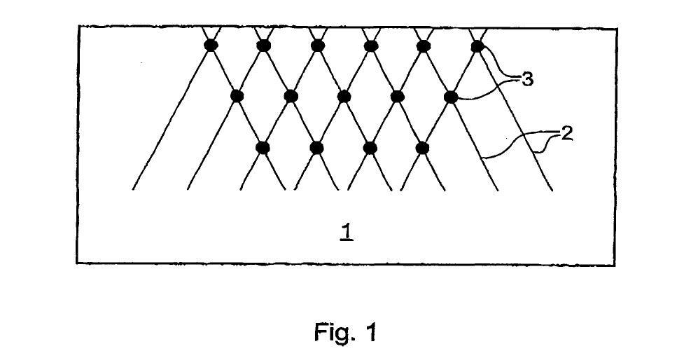

FIG. 1 shows a solid body (1) in which is formed a plurality of intersecting holes containing elongate solid state reinforcing members (2) flexibly joined at their intersections (3) by way of forces acting over a distance (in this case, electromagnetic forces).

The reinforced material is manufactured in the following way. Firstly, the intersecting holes are created inside the solid (1) by any appropriate method known in the art. A plurality of chains is then formed by connecting a number of elongate solid state reinforcing members (2) together in series by way flexible joints. A first set of chains is then inserted into a first set of holes in a first given direction (A), and a second set of chains in then inserted into a second set of holes in a second given direction (B). Further flexible joints (3) are then created where the chains intersect by using a mechanism of forces acting at a distance.

The flexible joints may alternatively be created by using a glue which preserves its elasticity after congelation or setting.

If the holes are in the form of pores, then the elongate solid state reinforcing members (2) flexible joints (3) inside the solid body (1) can originate from penetration of another material deposited on the surface of the solid body (1) and extending into its bulk.

The materials for the solid body (1) and the elongate solid state reinforcing members (2), as well as the type of flexible joint, may be selected on the basis of specific requirements for the operational characteristics of the reinforced material.

### EXAMPLES:

### 1) Nanometric Scale

A piezoceramic blank is produced using standard technology, having for example a composition: BaCO₃-19.8 mole %, TiO₂ -22.5 mole %, PbO -4.7 mole %, ZrO₂ -3.1 mole %, CaO-0.75 mole % (a pressed piezoceramic charge including a binding agent is baked at a temperature of 1300-1450° C. and then gradually and evenly cooled down).

Nano-pores are formed on one of the faces of the piezoceramic blank by an electroerosion method using a sharp probe of diameter 20 nm which is made, for example, from antimony sulfoiodide (SbSI). The electroerosion treatment is carried out by pulses of negative polarity with a scanning step of 600 nm, a modifying voltage of 4V and a processing time per pore of 400 ns.

Then a second probe, made for example of silver (with a sharp point of diameter 10 nm), is used to form silver nano-fibres inside the nano-pores. The nano-fibres are produced by a method of ion sedimentation during application of positive pulses (treatment step −600 nm, modifying voltage −2V, treatment time −600 ns). The first and second probes are positioned with the help of a scanning tunnelling electron microscope.

Mechanical deformation, under the influence of an external electric field of intensity 6 kV/mm, is then applied. As a result, the internal structure of the material turns into a net of pores with nano-fibres connected by joints.

After formation of pairs of “nano-fibre inside nano-pore” structures, input and output electrodes are formed with the help of an Ag-containing paste. Then, polarisation of the blank can occur.

A piezoceramic produced under the described method has nano-pores with a cross section of 20 to 100 nm and a depth of 300 to 1000 nm. Nano-fibres with a length of 300 to 1000 nm and a cross section of 10 to 100nm are embedded in the pores. The concentration of pores is on average 7 pores per μm². The nano-fibres are made of silver.

The tensile strength of the original piezoceramic plate without the “nano-fibre in nano-pore” structure is 2200 N/MM². The provision of a “nano-fibre in nano-pore” structure increases the tensile strength to 3100 N/mm². By providing flexible joints between intersecting nano-fibres, the tensile strength can be increased still further to 4400 N/MM².

i) Metal with Semiconducting Fibres Embedded into Pores.

Tungsten wire is used as a source material. A net of pores with a cross section of 20 to 100 nm is formed on the surface of the tungsten wire at a depth of 300 to 1000 nm with the help of mechanical deformation (by bending a 20 mm length wire at 2 mm intervals). Nano-fibres are embedded into the pores at a depth of 300 to 1000 nm and a cross section of 10 to 100 nm. The concentration of the pores is on average 5 pores per μm². The nano-fibres are made of silicon.

The tensile strength of the original tungsten wire without the “nano-fibre in nano-pore” structure is 3600 N/mm². With the use of a “nano-fibre in nano-pore” structure, the strength increases to 4400 N/mm . The described reinforced material has a strength of 5400 N/mm².

ii) Metal with dielectric fibres embedded into pores.

Tungsten wire is used as a source material. A net of pores with a cross section of 20 to 100 nm is formed on the surface of the tungsten wire at a depth of 300 to 1000 nm with the help of mechanical deformation (by bending a 20 mm length wire at 2 mm intervals). Nano-fibres are embedded into the pores at a depth of 300 to 1000 nm and a cross section of 10 to 100 nm. The concentration of the pores is on average 4 pores per μm². The nano-fibres are made of sulphur.

The tensile strength of the original tungsten wire is 3600 N/mm². The use of a “nano-fibre in nano-pore” structure increases the strength to 4100 N/mm². The described reinforced material has a strength of 4600 N/mm².

### 2) Macroscopic Scale:

A concrete mixture is formed from 15% weight Portland cement, 45% weight sand, 1% weight plasticising agent and 39% weight crushed stone (average stone particle weight 75 g). This mixture is then mixed with 50% weight water so as to form concrete.

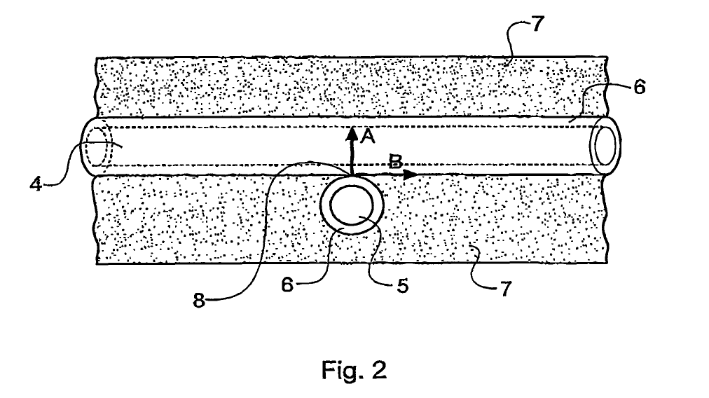

With reference now to FIG. 2, a matrix of steel reinforcement bars 4, 5 is then constructed, the bars each being provided with 1 mm thick PVC sleeves 6 which allow the bars 4, 5 to move slidably therein. In this example, the matrix comprises main longitudinal reinforcement bars 4 and auxiliary transverse reinforcement bars 5.

The reinforcement matrix is then placed in a mould and a concrete mixture 7 is poured over the matrix into the mould. A vibrator is applied for around 10 to 15 minutes so as to cause the concrete mixture 7 to settle properly, and the mould is then heated to 700° C. for 30 minutes so as to help the concrete 7 to set.

When the concrete 7 has set, as shown in FIG. 2, the PVC sleeves 6 of the steel reinforcement bars 4, 5 are pressed tightly together by the concrete 7. The PVC sleeves 6, at their points of intersection 8, are joined by way of electrostatic covalent bonds which have a transverse bond strength in the direction of arrow A of up to 6000 N/m², and a relatively lower longitudinal bond strength in the direction of arrow B of up to 500 N/m². The relatively low longitudinal bond strength provides the required flexibility in the join.

Compared to an equivalent traditional block of reinforced concrete in which the reinforcing bars are rigidly connected to each other, the reinforced concrete structure produced in accordance with this embodiment of the present invention has a tensile strength of 5600 N/m² as opposed to 4700 N/m².

What is claimed is:

1. A reinforced material comprising a solid body (1) having a plurality of intersecting holes formed therein and a plurality of elongate solid state reinforcing members (2) located within the holes, the elongate solid state reinforcing members (2) being flexibly mutually joined where they intersect with each other (3), and wherein the holes and the elongate solid state reinforcing members (2) have linear cross-sectional dimensions of less than 1 mm.

2. A reinforced material as claimed in claim 1, wherein the intersecting holes comprise pores.

3. A reinforced material as claimed in claim 2, wherein the pores and the elongate solid state reinforcing members (2) comprise widths or linear cross-sectional dimensions of 10 to 200 nanometres.

4. A reinforced material as claimed in claim 2, wherein the pores and the elongate solid state reinforcing members (2) comprise lengths of 100 to 1000 nanometres.

5. A reinforced material as claimed in claim 1, wherein the solid body (1) is made from dielectric material.

6. A reinforced material as claimed in claim 5, wherein at least part of the dielectric material comprises a ceramic material.

7. A reinforced material as claimed in claim 1, wherein the solid body (1) is made from semiconductor material.

8. A reinforced material as claimed in claim 1, wherein the solid body (1) is made from conductive material.

9. A reinforced material as claimed in claim 8, wherein at least part of the conductive material comprises silver.

10. A reinforced material as claimed in claim 8, wherein at least part of the conductive material comprises gold.

11. A reinforced material as claimed in claim 8, wherein at least part of the conductive material comprises platinum.

12. A reinforced material as claimed in claim 8, wherein at least part of the conductive material comprises copper.

13. A reinforced material as claimed in claim 1, wherein the elongate solid state reinforcing members (2) are made from dielectric material.

14. A reinforced material as claimed in claim 1, wherein the elongate solid state reinforcing members (2) are made from semiconductor material.

15. A reinforced material as claimed in claim 1, wherein the elongate solid state reinforcing members (2) are made from conductive material.

16. A reinforced material as claimed in claim 1, wherein the elongate solid state reinforcing members (2) are made from both dielectric material and semiconductor material.

17. A reinforced material as claimed in claim 1, wherein the elongate solid state reinforcing members (2) are made from both dielectric material and conductive material.

18. A reinforced material as claimed in claim 1, wherein the elongate solid state reinforcing members (2) are made from both semiconductor material and conductive material.

19. A reinforced material as claimed in claim 1, wherein the elongate solid state reinforcing members (2) are made from dielectric material, semiconductor material and conductive material.

20. A reinforced material comprising a solid body (1,7) having a plurality of intersecting holes formed therein and a plurality of elongate solid state reinforcing members (2,4,5) located within the holes, the elongate solid state reinforcing members (2,4,5) being flexibly mutually joined where they intersect with each other (3,8) and wherein the elongate solid state reinforcing members (2,4,5) are not affixed along their lengths to the solid state body (1,7).

21. A reinforced material as claimed in claim 20, wherein the elongate solid state reinforcing members (2,4,5) are smaller in cross-section that the elongate holes.

22. A reinforced material as claimed in claim 21, further comprising perimetral air gaps between the elongate solid state reinforcing members (2,4,5) and their associated elongate holes.

23. A reinforced material as claimed in claim 21, wherein at least some of the elongate solid state reinforcing members each comprise an internal member (4,5) and an external sleeve (6) which allow relative movement therebetween.

24. A reinforced material as claimed in claim 20, wherein the solid state material is concrete (7) and the elongate solid state reinforcing members (4,5) are metal.
